(19) United States
(12) Patent Application Publication
(10) Pub. No.: US 2026/0347997 A1
(43) Pub. Date: Nov. 5, 2026

(54) EVAPORATOR BOATS FOR METALLIZATION INSTALLATIONS

(71) Applicant: Kennametal Extrude Hone Corporation, Pittsburgh, PA (US)

(72) Inventors: Shuangyuan Zhang, Shanghai (CN); Zhenyang Li, Shanghai (CN); Hong Shi, Shanghai (CN); Zhou Zhipeng, Shanghai (CN)

(21) Appl. No.: 19/665,312

(22) Filed: May 1, 2026

Related U.S. Application Data
(60) Provisional application No. 63/798,902, filed on May 2, 2025.

(51) Int. Cl. C23C 14/24; C23C 4/08; C23C 4/10; C23C 4/123

(52) U.S. Cl. CPC C23C 14/243; C23C 4/08; C23C 4/10; C23C 4/123

(57) ABSTRACT

Evaporator boats are provided which, in some embodiments, exhibit resistance to corrosion and associated performance degradation imparted by exposure to molten metals, including aluminum. An evaporator boat, in some embodiments, comprises a body including a boron nitride (BN) component and a titanium diboride (TiB₂) component, and a thermal spray coating adhered to an evaporator surface of the body, wherein the thermal spray coating comprises one or more layers of metal, alloy, or refractory material, or combinations thereof.

### RELATED APPLICATION DATA

The present application claims priority pursuant to 35 U.S.C. § 119(e) to United States Provisional Application Ser. No. 63/798,902 filed May 2, 2025 which is incorporated herein by reference in its entirety.

### FIELD

The present invention relates to evaporator boats for metallization installations and, in particular, to evaporator boats employing thermal spray coatings applied to evaporator surfaces.

### BACKGROUND

A common method for coating flexible substrates with metals, such as aluminum, is vacuum band metallization according to PVD (physical vapor deposition) technology. Suitable flexible substrates include paper, plastic foils and textiles, and aluminum is mostly used as the metal. Such coated substrates are widely used for wrapping and decoration purposes, for the production of capacitors and in environmental technology (insulation). Coating of the flexible substrates takes place in metallization installations. In a metallization installation, the substrate to be coated is directed over a cooled roll while exposed to a metal vapor which condenses on the surface of the substrate as a thin metal layer. For generating the required constant vapor flow, electrically heatable evaporation boats are employed. Evaporation boats are generally heated to temperatures of 1450-1600 °C depending on metal. Metal wire is continuously supplied, liquefied on the surface of the vaporizer boat and vaporized under vacuum at approximately 10⁻⁴ mbar. Non-flexible substrates according to PVD-technology are coated batchwise in a discontinuous process, preferably by means of flash vaporization. Non-flexible substrates include television screens and plastic parts.

Evaporator boats used in continuous and the discontinuous methods generally consist of a hot-pressed ceramic material, the main components of which are titanium diboride and boron nitride. Titanium diboride is the electrically conductive component and boron nitride is the electrically insulating component, which, when mixed together, result in certain specific resistances. Over time, molten metal can attack and corrode the evaporator boat. Molten aluminum, for example, can dissolve TiB₂, wherein the dissolved TiB₂ precipitates at cold ends of the boat. BN can also react with molten aluminum forming aluminum nitride (AlN). In many cases, a porous AlN layer is formed on the evaporator body. The porous AlN layer can exhibit good electrical conductivity, lowering the electrical resistivity of the evaporator body.

Moreover, the reaction interface layer can deplete TiB₂. Lower electrical resistivity frustrates heating of the evaporator boat while TiB₂ depletion compromises electrical and mechanical properties of the boat. Such effects degrade boat performance and can induce premature boat replacement.

### SUMMARY

In one aspect, evaporator boats are provided which, in some embodiments, exhibit resistance to corrosion and associated performance degradation imparted by exposure to molten metals, including aluminum. An evaporator boat, in some embodiments, comprises a body including a boron nitride (BN) component and a titanium diboride (TiB₂) component, and a thermal spray coating adhered to an evaporator surface of the body, wherein the thermal spray coating comprises one or more layers of metal, alloy, or refractory material, or combinations thereof.

Weight percent of the BN component and TiB₂ component of the body can be set at any values not inconsistent with the objectives of the present invention. BN and TiB₂ weight percent can be selected according to several considerations including desired electrical resistivity, thermal conductivity and/or flexural strength of the evaporator boat. For example, weight percent of each of BN and TiB₂ can be set to provide the evaporator boat a specific electrical resistivity (1600 °C) of 600 to 6000 μΩ·cm. In some embodiments, an evaporator boat has a specific electrical resistivity selected from Table I.

TABLE I
Evaporator Boat Electrical Resistivity 1600 °C (μΩ · cm)

800-4000
2000-3500
2500-3500
2800-3400
2900-3300

The BN component, in some embodiments, is present in the evaporator boat in an amount of 25-75 weight percent. In other embodiments, weight percent of the BN component can be selected from Table II.

TABLE II
BN Component (wt. %)

30-70
35-65
40-60
45-55

Moreover, the TiB₂ component can be present in the evaporator body in an amount of 25-75 weight percent. In some embodiments, weight percent of the TiB₂ component can be selected from Table III.

TABLE III
TiB₂ Component (wt. %)

30-70
35-65
40-60
45-55

In some embodiments, the BN component and TiB₂ component are each present in the evaporator boat in an amount of 50 wt % (±5 wt %). Additionally, the BN component and TiB₂ component can each exhibit an average grain size of 1 μm to 20 μm. In some embodiments, the BN component and/or TiB₂ component have an average grain size of 5 μm to 20 μm or 10 μm to 20 μm. In further embodiments, the body of the evaporator boat comprises an aluminum nitride (AlN) component in addition to the BN and TiB₂ components. The AlN component can be present in any amount not inconsistent with the objectives of the present invention. For example, AlN can be present with BN and TiB₂ in an amount providing the evaporator boat a specific electrical resistivity selected from Table I.

As described herein, a thermal spray coating is adhered to an evaporator surface of the body, wherein the thermal spray coating comprises one or more layers of metal, alloy, or refractory material, or combinations thereof. The coating, in some embodiments, has a thickness of 0.1 μm to 500 μm or 10 μm to 100 μm. When present in the coating, the refractory material can comprise one or more metallic elements selected from the group consisting of aluminum and metallic elements of Groups 3-12 of the Periodic Table and one or more non-metallic elements selected from Groups 13-16 of the Periodic Table. In some embodiments, the refractory material comprises one or more metal carbides, metal oxides, metal nitrides, metal borides, metal carbonitrides, or mixtures thereof. For example, refractory materials of the coating can include Al₂O₃, AlN, AlON, AlCrN, TiAlN, TiOx, TiB₂, TiC, TiCN, TiN, ZrOₓ, ZrB₂, ZrN, ZrCN, W, WC, ZnOₓ, and/or Y₂O₃.

When present, the alloy comprises one or more transition metals selected from Groups 3-12 of the Periodic Table. Additionally, the coating can be formed of a single metal species or substantially formed of a single metal species. In some embodiments, for example, the coating is formed of Mo, W, Hf, Zr, Th, Tc, Ru, Ir, Nb, Pt, Ph, Os, Ta, or Re.

In some embodiments, the coating has a multilayer structure. Individual layers of the multilayer structure can have the same composition or differing compositions. In some embodiments, differing refractory materials can be employed across the individual layers.

Moreover, a coating can comprise individual layers having composition independently selected from refractory materials, alloys, and metals. In some embodiments, individual layers of a coating have a thickness of 100 nm to 100 μm. The individual layers of a coating can have the same or substantially the same thickness, in some embodiments. In other embodiments, thickness of the individual layers can vary in the coating. For example, the thickness of individual layers of the coating can increase in a direction away from the evaporator surface. In some embodiments, the thickness of individual layers of the coating can decrease in a direction away from the evaporator surface.

In some embodiments, the coating is not porous. For example, the coating can achieve full theoretical density or close to full theoretical density. Alternatively, the coating can exhibit porosity. In such embodiments, porosity can exist at the coating surface and/or in the bulk regions of the coating.

Coatings described herein exhibit good adhesion to the evaporator surface. In some embodiments, the coating exhibits an adhesion of at least 5 MPa or at least 10 MPa. Adhesion of the coating can range from 5 MPa to 50 MPa, in some embodiments. Coating adhesion is measured according to ASTM D3359.

In another aspect, methods of coating an evaporator boat are described herein. A method, in some embodiments, comprises providing an evaporator body including a boron nitride (BN) component and a titanium diboride (TiB₂) component, and applying a coating to an evaporator surface of the body by thermal spray, wherein the thermal spray coating comprises one or more layers of metal, alloy, or refractory material, or combinations thereof. The evaporator body and coating can have any composition and/or properties described herein. Powder metal, powder alloy, powder refractory material, or combinations thereof are used in the thermal spray application. In some embodiments, the powder metal, powder alloy, and/or powder refractory material have an average particle size of 10 μm to 150 μm.

These and other embodiments are further described in the following detailed description.

### BRIEF DESCRIPTION OF THE DRAWINGS

FIG. 1A is a top plan view of an evaporator surface comprising a thermal spray metallic coating described herein after metallizing about 270 km of aluminum film, according to some embodiments.

FIG. 1B is a top plan view of an uncoated evaporator surface after metallizing about 270 km of aluminum film.

### DETAILED DESCRIPTION

Embodiments described herein can be understood more readily by reference to the following detailed description and examples and their previous and following descriptions.

Elements, apparatus and methods described herein, however, are not limited to the specific embodiments presented in the detailed description and examples. It should be recognized that these embodiments are merely illustrative of the principles of the present invention. Numerous modifications and adaptations will be readily apparent to those of skill in the art without departing from the spirit and scope of the invention.

### Example 1—Coated Evaporator Boat

A tungsten-based alloy coating was applied to an evaporator surface of a BN/TiB₂ evaporator boat as follows:

Powder Preparation: The tungsten(W) alloy powder used for thermal spraying was substantially spherical, produced by gas atomization, water atomization, or melt fragmentation, with a purity of 99%. Particle size was between 5-70 μm.

### Substrate Preparation:

1. Mask: Align and fix the corresponding mask on the evaporation boat. Ensure the mask is secure to prevent movement during sandblasting and spraying.
2. Sandblasting: Use 80-mesh corundum sand at 0.7 MPa pressure, with a spray angle of 70-100° and a distance of 100-200 mm. Sandblast the masked area.
3. Spraying: Use atmospheric plasma spraying with parameters: Current is 600 A, 7 L/min hydrogen, 35 L/min argon, and a powder feed rate of 2.5 r/min. Repeat spraying 4-10 times based on thickness requirements.
4. Mask Removal: After spraying, remove the mask, organize it for reuse, and store the coated boat for sampling inspection.

### Example 2—Coated Evaporator Boat

A molybdenum-based alloy coating was applied to an evaporator surface of a BN/TiB₂ evaporator boat using the same process as set forth in Example 1. Spraying parameters were 500 A current, 1.5 L/min hydrogen, 45 L/min argon, 3 r/min powder feed rate.

### Example 3—Coated Evaporator Boat

An alumina (Al₂O₃) refractory coating was applied to an evaporator surface of a BN/TiB₂ evaporator boat using the same process as set forth in Example 1. Spraying parameters were 630 A current, 6 L/min hydrogen, 40 L/min argon, 3 r/min powder feed rate.

### Example 4—Coated Evaporator Boat

An yttria (Y₂O₃) refractory coating was applied to an evaporator surface of a BN/TiB₂ evaporator boat using the same process as set forth in Example 1. Spraying parameters were 580 A current, 5 L/min hydrogen, 45 L/min argon, 3 r/min powder feed rate.

### Example 5—Coated Evaporator Boat

An AT40 refractory coating was applied to an evaporator surface of a BN/TiB₂ evaporator boat using the same process as set forth in Example 1. Spraying parameters were 580 A current, 6 L/min hydrogen, 45 L/min argon, 3 r/min powder feed rate.

### Example 6—Coated Evaporator Boat

A titanium carbide (TiC) refractory coating was applied to an evaporator surface of a BN/TiB₂ evaporator boat using the same process as set forth in Example 1. Spraying parameters were 650 A current, 8 L/min hydrogen, 45 L/min argon, 3 r/min powder feed rate.

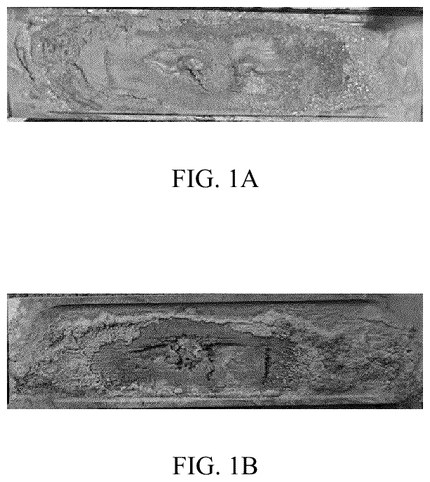

As an example, FIG. 1A is a top plan view of an evaporator surface comprising a thermal spray metallic coating described herein after metallizing about 270 km of aluminum film, according to some embodiments. FIG. 1B is a top plan view of an uncoated evaporator surface after metallizing about 270 km of aluminum film. The thermal spay coated evaporator surface of FIG. 1A shows substantially less wear and corrosion relative to the uncoated surface of FIG. 1B. Therefore, coated evaporator boats described herein can provide enhanced lifetimes.

Various embodiments of the invention have been described in fulfillment of the various objects of the invention. It should be recognized that these embodiments are merely illustrative of the principles of the present invention. Numerous modifications and adaptations thereof will be readily apparent to those skilled in the art without departing from the spirit and scope of the invention.

1. An evaporator boat comprising:
a body including a boron nitride (BN) component, a titanium diboride (TiB₂) component, and an optional aluminum nitride component; and
a thermal spray coating adhered to an evaporator surface of the body, wherein the thermal spray coating comprises one or more layers of metal, alloy, or refractory material, or combinations thereof.

2. The evaporator boat of claim 1, wherein the thermal spray coating has a thickness of 0.1 μm to 500 μm.

3. The evaporator boat of claim 1, wherein the thermal spray coating has a thickness of 100 nm to 100 μm.

4. The evaporator boat of claim 1, wherein the refractory material comprises one or more metallic elements selected from the group consisting of aluminum and metallic elements of Groups 3-12 of the Periodic Table and one or more non-metallic elements selected from Groups 13-16 of the Periodic Table.

5. The evaporator boat of claim 1, wherein the coating comprises a plurality of layers.

6. The evaporator boat of claim 5, wherein individual layers of the coating are formed of the same refractory material.

7. The evaporator boat of claim 5, wherein individual layers of the coating are formed of differing refractory materials.

8. The evaporator boat of claim 5, wherein individual layers of the coating have a thickness of 100 nm to 1 μm.

9. The evaporator boat of claim 5, wherein thickness of individual layers of the coating increases in a direction away from the evaporator surface.

10. The evaporator boat of claim 5, wherein thickness of individual layers of the coating decreases in a direction away from the evaporator surface.

11. The evaporator boat of claim 1, wherein the alloy comprises two or more transition metal selected from Groups 3-12 of the Periodic Table.

12. The evaporator boat of claim 1, wherein the coating is non-porous.

13. The evaporator boat of claim 1, wherein the coating exhibits an adhesion of at least 5 MPa.

14. The evaporator boat of claim 1, wherein the coating exhibits an adhesion of at least 10 MPa.

15. A method of coating an evaporator boat comprising:
providing an evaporator body including a boron nitride (BN) component, a titanium diboride (TiB₂) component, and an optional aluminum nitride component; and
applying a coating to an evaporator surface of the body by thermal spray, wherein the thermal spray coating comprises one or more layers of metal, alloy, or refractory material, or combinations thereof.

16. The method of claim 15, wherein powder metal, powder alloy, powder refractory material, or combinations thereof are used in the thermal spray application.

17. The method of claim 16, wherein the powder metal, powder alloy, and/or powder refractory material have an average particle size of 10 μm to 150 μm.

18. The method of claim 15 further comprising roughening the evaporator surface prior to applying the coating.

19. The method of claim 15 further comprising applying a mask to the evaporator body.

20. The method of claim 15, wherein the coating comprises a plurality of layers.

21. The method of claim 20, wherein individual layers of the coating have a thickness of 0.1 μm to 500 μm.

22. The method of claim 15, wherein the refractory material comprises one or more metallic elements selected from the group consisting of aluminum and metallic elements of Groups 3-12 of the Periodic Table and one or more non-metallic elements selected from Groups 13-16 of the Periodic Table.

23. The method of claim 15, wherein the alloy comprises two or more transition metals selected from Groups 3-12 of the Periodic Table.

24. The method of claim 20, wherein thickness of individual layers of the coating increases in a direction away from the evaporator surface.

25. The method of claim 20, wherein thickness of individual layers of the coating decrease in a direction away from the evaporator surface.

26. The method of claim 15, wherein the coating is non-porous.

27. The method of claim 15, wherein the coating exhibits an adhesion of at least 5 MPa.

28. The method of claim 15, wherein the coating exhibits an adhesion of at least 10 MPa.
